(19) United States
(12) Patent Application Publication
(10) Pub. No.: US 2009/0235969 A1
(43) Pub. Date: Sep. 24, 2009

(54) TERNARY THERMOELECTRIC MATERIALS AND METHODS OF FABRICATION

(75) Inventors: Joseph P. Heremans, Upper Arlington, OH (US); Vladimir Jovovic, Columbus, OH (US); Donald T. Morelli, White Lake, MI (US)

Correspondence Address: KNOBBE MARTENS OLSON & BEAR LLP, 2040 MAIN STREET, FOURTEENTH FLOOR, IRVINE, CA, 92614, US

(73) Assignees: The Ohio State University Research Foundation, Columbus, OH (US); The Board of Trustee of Michigan State University, East Lansing, MI (US)

(21) Appl. No.: 12/359,052

(22) Filed: Jan. 23, 2009

Related U.S. Application Data
(60) Provisional application No. 61/023,521, filed on Jan. 25, 2008.

(51) Int. Cl. H01L 35/12; C22C 5/06; C22C 12/00; C22C 28/00

(52) U.S. Cl. 136/236.1; 420/501; 420/576; 420/579

(57) ABSTRACT

A thermoelectric material and a method of fabricating a thermoelectric material are provided. The thermoelectric material includes a compound having an elemental formula of A₁₋ₓB_{1+y}C_{2+z} and having a coefficient of thermal expansion greater than 20 parts-per-million per degree Celsius in at least one direction at one or more operating temperatures. The A component of the compound includes at least one element selected from the group consisting of: at least one Group Ia element and at least one Group Ib element, the B component of the compound includes at least one element selected from the group consisting of: at least one Group V element and at least one Group VIII element, and the C component of the compound includes at least one Group VI element. In addition, x is between −0.2 and 0.3, y is between −0.2 and 0.4, and z is between −0.2 and 0.8. Furthermore, the A component includes no more than 95 atomic % silver when the B component includes antimony and the C component includes tellurium, the B component includes no more than 95 atomic % antimony when the A component includes silver and the C component includes tellurium, and the C component includes no more than 95 atomic % tellurium when the A component includes silver and the B component includes antimony.

This application claims the benefit of U.S. Provisional Application No. 61/023,521 filed Jan. 25, 2008, which is incorporated herein in its entirety by reference.

### BACKGROUND OF THE INVENTION

1. Field of the Invention

The present application relates generally to thermoelectric materials, and more specifically to ternary thermoelectric materials and methods of fabricating such materials.

2. Description of the Related Art

AgSbTe₂ is the paradigm for the class of I-V-VI₂ compound “semiconductors” where the Group V element is phosphorus, arsenic, antimony, or bismuth, the Group VI element sulfur, selenium, or tellurium, and the Group I element can be copper, silver, or gold (see, e.g., V. P. Zhuze, V. M. Sergeeva, and E. L. Shtrum, “Semiconducting compounds with the general formula ABX₂,” Sov. Phys. Techn. Phys., Vol. 3, pp. 1925-1938 (1958)) or alternatively an alkali metal, lithium, sodium, potassium, rubidium, or cesium (see, e.g., V. A. Bazakutsa and M. P. Vasilieva, “Thermal conductivity of triple semiconductors of A^{I}SbC^{VI}₂ type as a function of chemical composition and structure,” J. Engineering Physics, Vol. 34, pp. 137-140 (1978)).

Another class of similar semiconductors are the I-VIII-VI₂ compounds, where VIII stands for a Group VIII metal that can be trivalent, typically iron, cobalt, or nickel. Like PbTe, AgSbTe₂ crystallizes in the rock-salt structure (see, e.g., S. Geller and J. H. Wemick, “Ternary semiconducting compounds with sodium-chloride-like structure: AgSbSe₂, AgSbTe₂ AgBiS₂, AgBiSe₂,” Acta Cryst., Vol. 12, pp. 46-54 (1959)) with a similar lattice constant (a=0.6462 nanometer for PbTe and a/2=0.6076 nanometer for AgSbTe₂). AgSbTe₂ is also isoelectronic with PbTe in which the lead atom has a 2+ valence, and is replaced in AgSbTe₂ by one Ag¹⁺ and one Sb³⁺.

The first pure ternary I-V-VI₂ compounds were identified as chalcopyrites related to zinc-blende structures (see, e.g., C. H. L. Goodman and R. W. Douglas, “New semiconducting compounds of diamond type structure,” Physica, Vol. 20, pp. 1107-1109 (1954)). By 1957, rock-salt AgSbSe₂ and AgSbTe₂ were synthesized (see, e.g., J. H. Wernick and K. E. Benson, “New semiconducting ternary compounds,” Phys. Chem. Solids, Vol. 3, pp. 157-159 (1957)), and tentatively identified as narrow-gap semiconductors. A structural study (R. W. Armstrong, J. W. Faust Jr., and W. A. Tiller, “A structural study of the compound AgSbTe₂,” J. Appl. Phys., Vol. 31, pp. 1954-1959 (1960)) of AgSbTe₂ identified a complicated microstructure in the early samples, which was also reflected in an early galvanomagnetic and thermoelectric study (R. Wolfe, J. H. Wernick, and S. E. Haszko, “Anomalous Hall effect in AgSbTe₂,” J. Appl. Phys., Vol. 31, pp. 1959-1964 (1960)). It was noted early on that the room temperature thermal conductivity of AgSbTe₂ is extremely small, on the order of κ=0.63 W/mK (E. F. Hockings, “The thermal conductivity of silver antimony telluride,” Phys. Chem. Solids, Vol. 10, pp. 341-342 (1959)), and similarly low values were measured on other I-V-VI₂ compounds (see, e.g., [symbol] [symbol] [symbol] [symbol] “ [symbol] [symbol] [symbol] [symbol] A^{I}B^{V}B₂^{VI}” [symbol] [symbol] Hayk, Vol. 124, pp. 94-97 (1959) [Translation: L. D. Dudkin and A. L. Ostranitza, “Ternary Semiconductor Compounds A^{I}B^{V}B^{VI}₂,” Dokladi Akademyia NAUK SSSR, Vol. 124, pp. 94-97 (1959), not available in Sov. Phys.]).

Rosi et al. (F. D. Rosi, E. F. Hockings, and N. E. Lindenblad, “Semiconducting materials for thermoelectric power generation,” RCA Rev., Vol. 22, pp. 82-121 (1961)) recognized the potential of AgSbTe₂ as a thermoelectric material: it is the bulk p-type thermoelectric with a high figure of merit ZT (ZT=1.3 at 720 K, a temperature range relevant to applications of all simple ternary materials in electrical power generation that use fossil fuel combustion as a heat source (see, e.g., C. Wood, Rep. Prog. Phys., Vol. 51, pp. 459-539 (1988)). The thermoelectric figure of merit is a measure of the efficiency of thermoelectric devices, and is defined as Z=S²σ/κ, where S is the thermoelectric power or Seebeck coefficient, σ is the electrical conductivity, and κ is the thermal conductivity. It is customary to express the figure of merit as the unit-less product of Z with the average operating temperature T. As most thermoelectric materials are semiconductors in which κ is dominated by lattice conduction, it is also customary to group the electronic contributions into the “power factor” P=S²σ. In addition, unlike most materials used in thermoelectric power generation, AgSbTe₂ is lead-free and thus environmentally friendly.

Alloys of AgSbTe₂ and AgBiTe₂ with PbTe, SnTe, and GeTe (see, e.g., H. Fleischmann, O. G. Folberth, und H. Pfister, Zeitschrift für Naturforschung, Vol. 14a, pp. 999-1000 (1959) and H. Fleischmann, H. Luy, und J. Rupprecht, Zeitschrift far Naturforschung, Vol. 18a, pp. 646-649 (1963)) are well-studied thermoelectric materials. The recently reported AgPbₘSbTe₂₊ₘ bulk alloys (K. F. Hsu, S. Loo, F. Guo, W. Chen, J. S. Dyck, C. Uher, T. Hogan, E. K. Polychroniadis, and M. G. Kanatzidis, Science, Vol. 303, pp. 818-821 (2004)) have ZT=2.1 at 800 K. At first sight, these alloys can be considered as solid solutions of AgSbTe₂ with PbTe, although this view is clearly oversimplified (see, e.g., E. Quarez, K.-F. Hsu, R. Pcionek, N. Frangis, E. K. Polychroniadis, and M. G. Kanatzidis, J. Am. Chem. Soc., Vol. 127, pp. 9177-9190 (2005)).

In semiconducting (Group V)₂-(Group VI)₃ compounds, and in particular in Bi₂Te₃ and Sb₂Te₃, the Group V element (Bi, Sb) can go on the lattice site commonly occupied by the Group VI element (Te), creating what is called an anti-site defect (see, e.g., S. Scherer and H. Scherer, “CRC Handbook of Thermoelectricity,” D. M. Rowe, editor, CRC Press, Boca Raton, Fla. (1995)). In such cases, the excess Group B element dopes the material to be p-type. It is also possible for the stoichiometry of the (Group V)₂-(Group VI)₃ compound to vary considerably from the nominal values of 2:3.

### SUMMARY OF THE INVENTION

In certain embodiments, a thermoelectric material is provided. The thermoelectric material comprises a compound having an elemental formula of A₁₋ₓB_{1+y}C_{2+z} and having a coefficient of thermal expansion greater than 20 parts-per-million per degree Celsius in at least one direction at one or more operating temperatures. The A component of the compound comprises at least one element selected from the group consisting of: at least one Group Ia element and at least one Group Ib element, the B component of the compound comprises at least one element selected from the group consisting of: at least one Group V element and at least one Group VIII element, and the C component of the compound comprises at least one Group VI element. In addition, x is between −0.2 and 0.3, y is between −0.2 and 0.4, and z is between −0.2 and 0.8. Furthermore, the A component comprises no more than 95 atomic % silver when the B component comprises antimony and the C component comprises tellurium, the B component comprises no more than 95 atomic % antimony when the A component comprises silver and the C component comprises tellurium, and the C component comprises no more than 95 atomic % tellurium when the A component comprises silver and the B component comprises antimony.

In certain embodiments, a thermoelectric material is provided. The thermoelectric material comprises a compound having an elemental formula of A₁₋ₓB_{1+y}C_{2+z} and having a Grüneisen parameter greater than 1.6 at one or more operating temperatures. The A component of the compound comprises at least one element selected from the group consisting of: at least one Group Ia element and at least one Group Ib element, the B component of the compound comprises at least one element selected from the group consisting of: at least one Group V element and at least one Group VIII element, and the C component of the compound comprises at least one Group VI element. In addition, x is between −0.2 and 0.3, y is between −0.2 and 0.4, and z is between −0.2 and 0.8. Furthermore, the A component comprises no more than 95 atomic % silver when the B component comprises antimony and the C component comprises tellurium, the B component comprises no more than 95 atomic % antimony when the A component comprises silver and the C component comprises tellurium, and the C component comprises no more than 95 atomic % tellurium when the A component comprises silver and the B component comprises antimony.

In certain embodiments, a thermoelectric material is provided. The thermoelectric material comprises a compound having an elemental formula of A₁₋ₓB_{1+y}C_{2+z} and having a coefficient of thermal expansion greater than 20 parts-per-million per degree Celsius in at least one direction at one or more operating temperatures. The A component of the compound comprises at least one element selected from the group consisting of: at least one Group Ia element and at least one Group Ib element, the B component of the compound comprises at least one element selected from the group consisting of: at least one Group V element and at least one Group VIII element, and the C component of the compound comprises at least one Group VI element. Furthermore, x is non-zero, y is non-zero, and z is non-zero.

In certain embodiments, a thermoelectric material is provided. The thermoelectric material comprises a compound having an elemental formula of A₁₋ₓB_{1+y}C_{2+z} and having a Grüneisen parameter greater than 1.6 at one or more operating temperatures. The A component of the compound comprises at least one element selected from the group consisting of: at least one Group Ia element and at least one Group Ib element, the B component of the compound comprises at least one element selected from the group consisting of, at least one Group V element and at least one Group VIII element, and the C component of the compound comprises at least one Group VI element. Furthermore, x is non-zero, y is non-zero, and z is non-zero.

In certain embodiments, a thermoelectric material is provided. The thermoelectric material comprises a compound having an elemental formula of A₁₋ₓB_{1+y}C_{2+z} and having a polycrystalline structure with at least one crystal having a volume greater than about 0.0001 mm³. The A component of the compound comprises at least one element selected from the group consisting of: at least one Group Ia element and at least one Group Ib element, the B component of the compound comprises at least one element selected from the group consisting of: at least one Group V element and at least one Group VIII element, and the C component of the compound comprises at least one Group VI element. Furthermore, x is between −0.2 and 0.3, y is between −0.2 and 0.4, and z is between −0.2 and 0.8.

In certain embodiments, a thermoelectric material is provided. The thermoelectric material comprises a compound having an elemental formula of A₁₋ₓB_{1+y}C_{2+z}. The A component of the compound comprises at least one element selected from the group consisting of: at least one Group Ia element and at least one Group Ib element, the B component of the compound comprises at least one element selected from the group consisting of: at least one Group V element and at least one Group VIII element, and the C component of the compound comprises at least one Group VI element. Furthermore, x is between −0.2 and 0.3, y is between −0.2 and 0.4, and z is between −0.2 and 0.8. In addition, the thermoelectric properties of the compound are substantially independent of any nanometer-sized inclusions within the compound.

In certain embodiments, a thermoelectric material is provided. The thermoelectric material comprises a compound having an elemental formula of A₁₋ₓB_{1+y}C_{2+z}. The A component of the compound comprises at least one element selected from the group consisting of: at least one Group Ia element and at least one Group Ib element, the B component of the compound comprises at least one element selected from the group consisting of: at least one Group V element and at least one Group VIII element, and the C component of the compound comprises at least one Group VI element. Furthermore, x is between −0.2 and 0.3, y is between −0.2 and 0.4, and z is between −0.2 and 0.8. In addition, the compound is doped with a dopant level greater than about 5×10¹⁹ cm⁻³.

In certain embodiments, a method of fabricating a thermoelectric material is provided. The method comprises placing a plurality of materials in a container. The plurality of materials comprises a first amount of at least one element selected from the group consisting of; at least one Group Ia element and at least one Group Ib element, a second amount of at least one element selected from the group consisting of: at least one Group V element and at least one Group VIII element, and a third amount of at least one Group VI element. The first amount, the second amount, and the third amount have the molar ratios of (1−x):(1+y):(2+z), respectively with x between −0.2 and 0.3, y between −0.2 and 0.4, and z between −0.2 and 0.8. The method further comprises sealing the plurality of materials within the container under vacuum and exposing the materials within the container to a predetermined temperature profile.

In certain embodiments, a thermoelectric material is provided. The thermoelectric material comprises a solid solution of two or more compounds having an elemental formula of A₁₋ₓB_{1+y}C_{2+z}. The A component of the compound comprises at least one element selected from the group consisting of: at least one Group Ia element or Group Ib element, the B component of the compound comprises at least one element selected from the group consisting of, at least one Group V element or at least one Group VIII element, and the C component of the compound comprises at least one Group VI element. Furthermore, x is between −0.2 and 0.3, y is between −0.2 and 0.4, and z is between −0.2 and 0.8.

### BRIEF DESCRIPTION OF THE DRAWINGS

FIG. 1 is a flow diagram of an example method compatible with certain embodiments described herein.

FIG. 2 schematically illustrates an example temperature profile compatible with certain embodiments described herein.

FIG. 3 is a plot of a thermoelectric figure of merit ZT of p-type AgSbTe₂ as a function of the acceptor-type impurities for the various temperatures shown up to the melting point of the material.

FIG. 4 is a plot of measured (a) specific heat, (b) thermal diffusivity, and (c) thermal conductivity of undoped (circle) AgSbTe₂ sample and material doped with 2% AgTe (square), 1% NaSe_{0.5}Te_{0.5} (solid diamond), 1% NaTe (open diamond), 1.5% TITe (X), 1% BiTe (star), and 1% excess Pb (cross), and static heater and sink method was used to measure thermal conductivity in temperature range 80 K to 300 K on undoped sample (solid line) and sample doped with excess Ag (dashed line).

FIG. 5 is a plot of electrical resistivity and Seebeck coefficient of doped AgSbTe₂ materials.

FIG. 6 is a plot of Zero-field adiabatic Nernst coefficient and Hall coefficient of undoped (circle) AgSbTe₂ sample and material doped with 2% AgTe (square), 1% NaSe_{0.5}Te_{0.5} (solid diamond), 1% NaTe (open diamond), 1.5% TlTe (X), 1% BiTe (star), and 1% excess Pb (cross).

FIG. 7 is a plot of ZT as a function of temperature for AgSbTe₂ and AgSbTe₂ doped with 2 atomic % AgTe, 1 atomic % NaSe_{0.5}Te_{0.5}, 1 atomic % NaTe, 1.5 atomic % TITe, or 1 atomic % BiTe, and 1 atomic % Pb.

### DETAILED DESCRIPTION

As used herein, the term “Group Ia element” refers to at least one element of the group consisting of: lithium, sodium, potassium, rubidium, and cesium. As used herein, the term “Group Ib element” refers to at least one element of the group consisting of: copper, silver, and gold. As used herein, the term “Group V element” refers to at least one element of the group consisting of: phosphorus, arsenic, antimony, and bismuth. As used herein, the term “Group VI element” refers to at least one element of the group consisting of: oxygen, sulfur, selenium, and tellurium. As used herein, the term “Group VIII element” refers to at least one element of the group consisting of iron, cobalt, nickel, ruthenium, rhodium, palladium, osmium, iridium, and platinum.

Certain embodiments described herein address the need for a thermoelectric compound with a high figure of merit ZT. Conventional materials generally have a figure of merit ZT<1, thereby limiting the applications of such materials to niche markets. Certain embodiments described herein provide a thermoelectric material with ZT>1.5 to 1.7 at its operating temperature. Thermoelectric power generators and heat pumps that utilize thermoelectric materials with ZT>1.5 have efficiencies competitive with conventional heat engines, such as internal combustion motors or vapor-compression refrigerators and air conditioners. Applications of certain embodiments described herein include, but are not limited to, auxiliary power units using a heat source at about 500-550° C. (e.g., as produced by burning fossil fuels), solar heat produced by concentrating sunlight onto a light absorber to create solar-thermal power, and distributed air conditioning systems. Further examples of thermoelectric power systems are disclosed in U.S. Pat. Nos. 6,539,725, 7,231,772, 6,959,555, 6,625,990, and 7,273,981, which are incorporated herein in their entirety by reference.

Band structure calculations (K. Hoang, S. D. Mahanti, J. R. Salvador, and M. G. Kanatzidis, “Atomic Ordering and Gap Formation in Ag—Sb-Based Ternary Chatcogenides,” Phys. Rev. Lett., Vol. 99, pp. 156403 (2007)) for AgSbTe₂ show a dependence of the energy bands on the ordering of the metal (Group I-Group V) sublattice. Certain embodiments described herein utilize a new preparation method, described in V. Jovovic and J. P. Heremans, “Galvanomagnetic and thermomagnetic properties of AgSbTe₂,” Phys. Rev. B. Vol. 77c, pp. 245204 (2008) and is incorporated herein in its entirety by reference, that creates uniform material with a low concentration of crystalline defects.

Samples of ternary thermoelectric materials (e.g., A₁₋ₓB_{1+y}C_{2+z}) were prepared using a method of growing and heat treating high purity (e.g., at least 90% pure) samples for thermoelectric applications in accordance with certain embodiments described herein. In certain embodiments, the ternary thermoelectric materials have ratios of atomic concentrations of the constituents which deviate significantly from the nominal values. For example, for (Group I)-(Group V)-(Group VI)₂ compounds, the ratio of the atomic concentrations of the Group I element, the Group V element, and the Group VI element can deviate significantly from the nominal values of 1:1:2. Rather than using the nominal ABC₂ formula, such compounds can be denoted by A₁₋ₓB_{1+y}C_{2+z}, where x, y, and z deviate from zero (e.g., x is non-zero, y is non-zero, and z is non-zero, or x is between −0.2 and 0.3, y is between −0.2 and 0.4, and z is between −0.2 and 0.8).

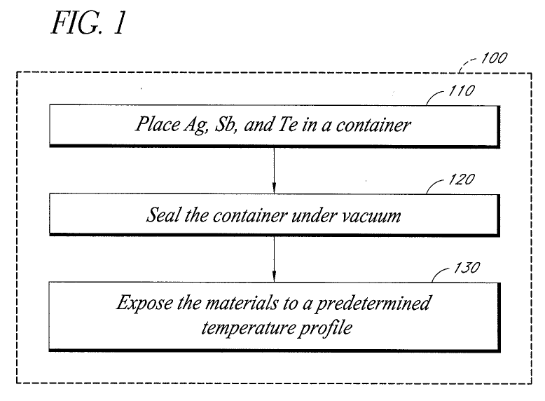

FIG. 1 is a flow diagram of an example method 100 compatible with certain embodiments described herein. In an operational block 110, silver, antimony, and tellurium are placed in a container in predetermined molar ratios (e.g., 1:1:2 for Ag, Sb, and Te, respectively). In certain embodiments, elemental silver, antimony, and tellurium are used, while in certain other embodiments, the compounds Ag₂Te and Sb₂Te₃ are used. In still other certain embodiments, combinations of the elemental forms and the Ag₂Te and Sb₂Te₃ compounds are used. In certain embodiments, the container comprises a quartz ampoule. In certain other embodiments in which other elements are used (e.g., at least one Group Ia element, at least one Group Ib element, at least one Group V element, at least one Group VIII element, at least one Group VI element), the elemental forms and/or compound forms can be used.

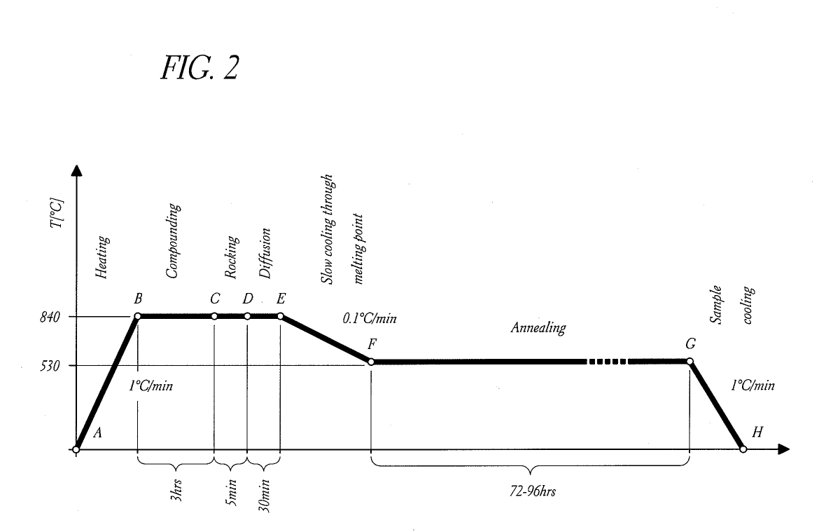

In an operational block 120, the container is sealed under vacuum (e.g., at a pressure less than about 10-5 torr). In an operational block 130, the material within the sealed container is exposed to a predetermined temperature profile. FIG. 2 schematically illustrates an example temperature profile compatible with certain embodiments described herein. In this example temperature profile, the material within the sealed container is heated from room temperature to about 840° C. at a rate of about 1° C./minute (A to B). In this example temperature profile, the material is then kept at a substantially constant temperature of about 840° C. for about three hours (B to C), followed by furnace rocking for about five minutes (C to D), and the material is allowed to compound for an additional time period of about 30 minutes (D to E). The material is then slowly cooled through the melting point at a rate of about 0.1° C./minute. For example, as shown in FIG. 2, the material is cooled from about 840° C. at point F to about 530° C. at point F. The material is then annealed (F to C) at a predetermined annealing temperature (e.g., about 530° C.) for a predetermined time period (e.g., 72 to 96 hours). The material is then cooled from the annealing temperature to room temperature (G to H) at a predetermined rate (e.g., about 1° C./minute). As used herein in conjunction with temperatures, the term “about” has its broadest reasonable meaning, including, but not limited to, within a deviation of 40° C. above the nominal temperature and 40° C. below the nominal temperature. While the temperatures cited above and in FIG. 2 correspond to the fabrication of AgSbTe₂, other materials in accordance with certain embodiments described herein can be fabricated using temperatures which are scaled accordingly with the melting point of the formed compound.

Using the example temperature profile of FIG. 2, samples of Ag₁₋ₓSb_{1+y}Te_{2+z} (e.g., x=1/12=0.0825; y=1/8=0.125; z=1/16=0.0625, which can be expressed as Ag₂₂Sb₂₇Te₅₁) having polycrystalline structure with large crystallites with volumes greater than about 0.0001 mm³ (e.g., in a range between about 0.0001 mm³ and about 0.0003 mm³) were formed. These samples had an intergranular phase of Ag₂Te at boundaries between the large crystalline grains. Galvanomagnetic and thermomagnetic experiments were conducted on these samples with the intragranular phase removed mechanically identified the compound as a very narrow-gap semiconductor, with an energy gap on the order of 7 meV, a heavy valence band and a very light high-mobility electron band. A study of the thermal conductivity of these high-quality samples with the intragranular phase removed mechanically found that the lattice thermal conductivity of these samples were intrinsically limited by phonon-phonon interactions to the minimum possible value, 0.63 W/mK (D. T. Morelli, J. P. Heremans, V. Jovovic, “Intrinsically minimal thermal conductivity of AgSbTe₂,” Phys. Rev. Lett., Vol. 101, pp. 035901 (2008), which identified the compound of these samples as AgSbTe₂, and is incorporated herein in its entirety by reference). This value is reached when the mean free path of the acoustic waves (phonons) that carry the heat is reduced to its minimum possible value, namely the distance between two atoms in the crystal lattice (about 0.3 nanometer in AgSbTe₂). The lattice thermal conductivity of such compounds is then approximately temperature-independent. This result is in contrast to that of Rosi et al. which described measurements made presumably from a two-phased material having a non-uniform distribution of Ag. Rosi et al. ascribed a measured low thermal conductivity to defects and non-uniformities in the material, rather than an intrinsic property of the material.

Compositional studies of large grains cut out of the Ag—Sb—Te₂ material measured the composition to be Ag₂₂Sb₂₇Te₅₁, which is enriched in antimony compared to the nominal composition AgSbTe₂. Since the large grains were p-type, it can be concluded that the excess Sb goes to the Te sites in the lattice, where it acts as an electron acceptor. Therefore, for (Group I)-(Group V)-(Group VI)₂ compounds, the ratio of the atomic concentrations of the Group I to Group V to Group VI elements can deviate significantly from the nominal values of 1:1:2. In certain embodiments, the chemical composition of the large grains is Ag₁₋ₓSb_{1+y}Te_{2+z} with 0≦x≦0.1, 0≦y≦0.15 and 0≦z≦0.1.

The single crystals of the Ag₂₂Sb₂₇Te₅₁ compound were determined to be p-type, yet they have excess Sb, which is a trivalent metal (Sb³⁻). Without being bound by theory, this behavior can be understood by considering the Ag₂₂Sb₂₇Te₅₁ to be analogous, not to PbTe, but to Sb₂Te₃. In PbTe, the main defect is a vacancy: absence of Te on a Te site. In that case, more Te dopes the material p-type, and more Pb dopes the material n-type. Because Sb is a Group V element, it also exists as Sb⁵⁻=Sb³⁺, and on a Te site, it acts as an acceptor, not a donor as it does in PbTe (where it sits on a Pb site). In Bi₂Te₃ and Sb₂Te₃, adding Bi or Sb above stoichiometry puts those atoms on the Te sites, and the sample becomes p-type. This occupation by the excess Sb atoms on Te sites in Ag₂₂Sb₂₇Te₅₁ can presumably explain its p-type property. The nominal composition would be Ag₂₄Sb₂₄Te₄₈, but in Ag₂₂Sb₂₇Te₅₁ there are two atoms too few of Ag, three atoms too many of Sb, and three atoms too many of Te, such that three Sb atoms of every 24 go onto Te sites and dope the material p-type.

In addition, a study by Hsu et at of alloys of AgSbTe₂ with PbTe reported a low thermal conductivity and a high figure of merit. Hsu et al ascribed this result to the presence of nanometer-scale inclusions in the alloy. This interpretation is in strong contrast to the observation described below for stoichiometric and off-stoichiometric AgSbTc₂ with large and uniform grains, in which the low thermal conductivity is ascribed to intrinsic phonon-phonon processes. In certain embodiments described herein, the thermoelectric properties of the compound are substantially independent of any nanometer-sized inclusions within the compound.

Our study of these high-quality samples show that stoichiometric and off-stoichiometric AgSbTe₂ (e.g., Ag₁₋ₓSb_{1+y}Te_{2+z} such as Ag₂₂Sb₂₇Te₅₁) are unique examples of a crystalline material whose lattice thermal conductivity exhibits the minimum possible value due to intrinsic phonon processes alone. This fact makes certain embodiments described herein extremely robust to manufacturing process variations, and it ensures that certain embodiments described herein will be stable during long-term operation at elevated temperatures. Both these points give certain embodiments described herein comprising AgSbTe₂, or other members of this general type of material (e.g., Ag₁₋ₓSb_{1+y}Te_{2+z}) an advantage over thermoelectric materials containing nanoparticles, which are much more difficult to prepare, and can dissolve or grow at high operating temperature. In addition, the high valence band effective masses make Ag₁₋ₓSb_{1+y}Te_{2+z} a very advantageous thermoelectric material.

The anharmonicity of the chemical bond drives the phonon-phonon Umklapp and Normal processes that intrinsically limit the high-temperature lattice thermal conductivity (see, e.g., A. F. Ioffe, “Physics of semiconductors,” London, Infosearch, (1958)). Octahedral coordination in the rock-salt semiconductors such as PbTe has a high degree of anharmonicity, which lowers their lattice thermal conductivity κ_{L} by about a factor of 4 compared to tetrahedrally-bonded semiconductors with similar or better electronic properties such as GaAs, InAs, and InSb (see, e.g., D. T. Morelli and G. A. Slack, “High Lattice Thermal Conductivity Solids,” p. 37 in High Thermal Conductivity Materials, ed. S. Shinde and J. Goela, New York, Springer (2005)); this in turn leads to much larger ZT values, even though the III-V materials have a higher mobility and thus often a higher power factor. The unit cells of the I-V-VI₂ semiconductors are generally twice the volume of the unit cells of the IV-VI materials, and have a correspondingly lower κ_{L}. AgSbTe₂ in particular possesses an anharmonicity even higher than that of PbTe, resulting in a phonon-phonon-limited lattice thermal conductivity κ_{L} that is smaller by an additional factor of four.

The high temperature limit of the acoustic phonon mode Grüneisen parameter is γ, which is a direct measure of the anharmonicity of the bonds, and defined as (see, e.g., E. Grüneisen, Handbuch der Physik, edited by H. Geiger and K. Scheel, Vol. 10, pp. 1-59, Berlin, Springer-Verlag (1926));

$$γ = \frac{β {BV}_{m}}{{C}_{v}} , \qquad ( 1 )$$

where β is the volume thermal expansion coefficient, B is the isothermal bulk modulus, Cᵥ the isochoric specific heat per mole, and Vₘ is the molar volume. Consequently, members of the I-V-VI₂ and the I-VII₁-VI₂ compounds, other than AgSbTe₂ itself, can also be identified as thermoelectric materials. While Rosi et al. identified AgSbTe₂ as being a candidate thermolelectric material, Rosi et al. did not identify other members of the I-V-VI₂ and the I-VIII-VI₂ compounds as thermoelectric materials.

In certain embodiments described herein, either the Grüneisen parameter 7 or the volume thermal expansion coefficients is used as a condition for material selection. The volume thermal expansion coefficient is related to the linear thermal expansion coefficient along each of the three principal crystallographic axes, and the linear thermal expansion coefficient can be used to identify thermoelectric materials from amongst the members of the I-V-VI₂ and the I-VII₁-VI₂ compounds that crystallize as chalcopyrite or rock-salts. For example, a material is identified as a thermoelectric material in accordance with certain embodiments described herein if it comprises one or more I₁₋ₓ-V_{1+y}-VI_{2+z}, (e.g., I-V-VI₂) or I₁₋ₓ-VIII_{1+y}-VI_{2+z} (e.g., I-VII₁-VI₂) compounds with a Grüneisen parameter greater than 1.6 at one or more operating temperatures. As another example, a material is identified as a thermoelectric material in accordance with certain embodiments described herein if it comprises one or more I₁₋ₓ-V_{1+y}-VI_{2+z} (e.g., I-V-VI₂) or I₁₋ₓ-VIII_{1+y}-VI_{2+z} (e.g., I-VIII-VI₂) compounds with a coefficient of thermal expansion greater than 20 parts-per-million (ppm) per degree Celsius in at least one direction at one or more operating temperatures. In certain embodiments, the thermoelectric material has a cubic crystal structure which is isotropic so the Grüneisen parameter and the coefficient of thermal expansion are isotropic as well.

Certain embodiments described herein predict the thermoelectric figure of merit for p-type Ag₁₋ₓSb_{1+y}Te_{2+z} (e.g., AgSbTe₂) at different temperatures and at different doping levels, using knowledge gained from measurements of the lattice thermal conductivity and of the band parameters of high-quality samples of p-type Ag₁₋ₓSb_{1+y}Te_{2+z}. For example, the band structure parameters are used and the appropriate equations are solved to derive the Seebeck coefficient, the electrical conductivity, and the electronic contribution to the thermal conductivity. The lattice thermal conductivity measurements are then used to calculate the thermoelectric figure of merit ZT at each temperature and doping level.

In certain embodiments, the thermoelectric material is n-type doped with one or more extrinsic dopants selected from the group consisting of: titanium, tantalum, niobium, zinc, maganese, aluminum, gallium, indium, at least Group III element, at least one Group V element, and at least one Group VIII element. In certain embodiments, the thermoelectric material is p-type doped with one or more dopants comprising thallium. In certain embodiments, the thermoelectric material is p-type doped with a dopant level greater than about 5×10¹⁹ cm⁻³. In certain embodiments, the one or more dopants can comprise off-stoichiometry amounts of the ternary elements (e.g., A₁₋ₓB_{1+y}C_{2+z}) and/or extrinsic dopants. As used herein, the term “dopant level” has its broadest reasonable meaning, including but not limited to, the extrinsic carrier concentration not from thermal effects, but from effects induced by chemistry changes (e.g., by adding foreign atoms or by varying the stoichiometry of the A₁₋ₓB_{1+y}C_{2+z} compound).

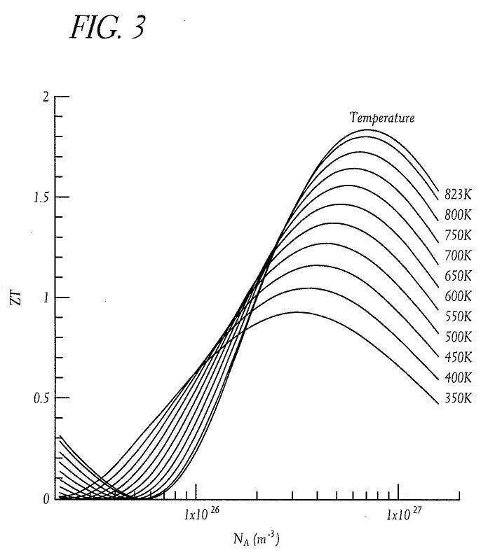

The results of these calculations are shown in FIG. 3, which illustrates that an optimum acceptor doping level (e.g., the doping level that maximizes the curves of FIG. 3) for AgSbTe₂ is on the order of 5×10²⁵ to 10²⁷ m⁻³ (5×10¹⁹ to 10²¹ cm⁻³), which is considerably higher than in conventional thermoelectric materials where it is on the order of 1 to 5×10¹⁹ cm³. In certain embodiments, the acceptor doping level is in a range between about 5×10¹⁹ cm⁻³ and about 10²¹ cm³, in a range between about 10²⁰ cm³ and about 10²¹ cm⁻³, or in a range between about 2×10²⁰ cm³ and about 10²¹ cm⁻³. In certain embodiments, the high dopant concentrations are advantageously used in AgSbTe₂ to overcome the effect of the thermally excited electrons which decrease the total Seebeck coefficient. This behavior is the result of the extremely narrow energy gap in AgSbTe₂ and is quite counter-intuitive given the results of Rosi et al. In order to increase the Seebeck coefficient of p-type AgSbTe₂, certain embodiments described herein advantageously increase the density of acceptor atoms in this material above 10²⁰ cm⁻³. Conversely, in practically every other semiconductor the opposite is true. Consequently, p-type doped AgSbTe₂ can be used as a thermoelectric material.

In certain embodiments, the Ag₁₋ₓSb_{1+y}Te_{2+z} (e.g., AgSbTe₂) compound is p-type doped with at least one dopant selected from the group consisting of: a Group I element lithium, sodium, indium, gallium, aluminum, and thallium. In certain embodiments, the Ag₁₋ₓSb_{1+y}Te_{2+z} (e.g., AgSbTe₂) compound is p-type doped such that the compound comprises an excess amount of one or more chalcogen elements. In certain embodiments, the Ag₁₋ₓSb_{1+y}Te_{2+z} (e.g., AgSbTe₂) compound is p-type doped with excess silver. In certain embodiments, the Ag₁₋ₓSb_{1+y}Te_{2+z} (e.g., AgSbTe₂) compound is p-type doped with an atomic concentration of silver greater than an atomic concentration of antimony in the compound, In certain embodiments, the Ag₁₋ₓSb_{1+y}Te_{2+z} (e.g., AgSbTe₂) compound is p-type doped with excess antimony. In certain embodiments, the atomic concentration of antimony is greater than the atomic concentration of silver. In certain embodiments, the atomic concentration of antimony is greater than the atomic concentration of silver and the atomic concentration of tellurium is smaller than the sum of the atomic concentrations of Sb and Ag.

In certain embodiments, the Ag₁₋ₓSb_{1+y}Te_{2+z} (e.g., AgSbTe₂) compound is n-type doped with at least one dopant selected from the group consisting of: titanium, tantalum, niobium, zinc, maganese, aluminum, gallium, indium, at least one Group III element, at least one Group V element, and at least one Group VIII element. In certain embodiments, the Ag₁₋ₓSb_{1+y}Te_{2+z} (e.g., AgSbTe₂) compound is n-type doped with an atomic concentration of antimony greater than an atomic concentration of silver in the compound, with the atomic concentration of silver less than the atomic concentration of antimony in the compound and the atomic concentration of tellurium is equal or greater than the sum of the atomic concentrations of silver and antimony.

Several Ag₁₋ₓSb_{1+y}Te_{2+z} (e.g., AgSbTe₂) doped samples were prepared. AgSbTe₂ samples doped with NaTe, NaSe_{0.5}Te_{0.5}, TlTe, BiTe, excess Pb, and simultaneous excess of Ag and Te (labeled AgTe), were prepared by melting the elements of 99.999% or higher purity in quartz ampoules following the process used in Morelli et al. and Jovovic et al. Resulting materials were of polycrystalline structure with crystallite size about 3 mm³ and larger. It was been noticed that materials alloyed with Na have significantly larger crystallite size of about 7 mm³ to 8 mm³ and that they readily cleave. The studied samples all had cubic structure as confirmed by powder x-ray diffraction (XRD). Based on the analysis of powder x-ray data, materials prepared with excess Ag tended to have regions of an Ag₂Te phase that segregates presumably at grain boundaries. In contrast, no phase separation was observed in the other samples prepared by this technique. Samples with similar XRD traces have shown quantum oscillations (see e.g., Jovovic et al.), so eventual traces of segregation likely have a minimal influence on the transport properties at temperatures below the known phase transition of Ag₂Te, 145° C.

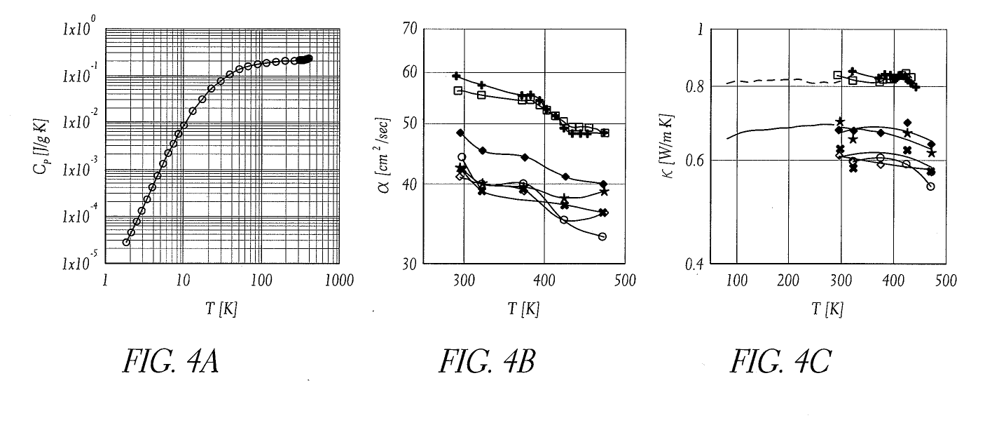

Thermal conductivity data in the temperature range 80 K to 300 K were taken on several samples with cross-sections of about 9 mm² using a static heater and sink method. The heat flux was measured and maintained at approximately 4 mW/K. The temperature differential was measured using copper-constantan thermocouples with distance between probes of 1.75±0.03 mm. Thermal losses were minimized by the use of radiation shields and thin thermocouple wires. Estimated losses are on the order of 10% and are not corrected for in the results. In FIG. 4(c), two sets of thermal conductivity data were measured using the static method, the solid line referring to undoped AgSbTe₂ of resistivity 7×10⁻⁵ Ωm at room temperature and the dashed line referring to the more electrically conducting sample doped with 2 at. % excess Ag over Sb. The lattice thermal conductivity of these materials is about κ_{L}=0.61 W/mK and that the total electronic component of thermal conductivity (κₑ) is dominated by the ambipolar (κ_{ambi}) term κₑ=κ_{ambi}+κₑ^{h}+κₑ^{e} in the undoped materials; κₑ^{h} and κₑ^{e} are electronic thermal conductivities of holes and electrons, respectively.

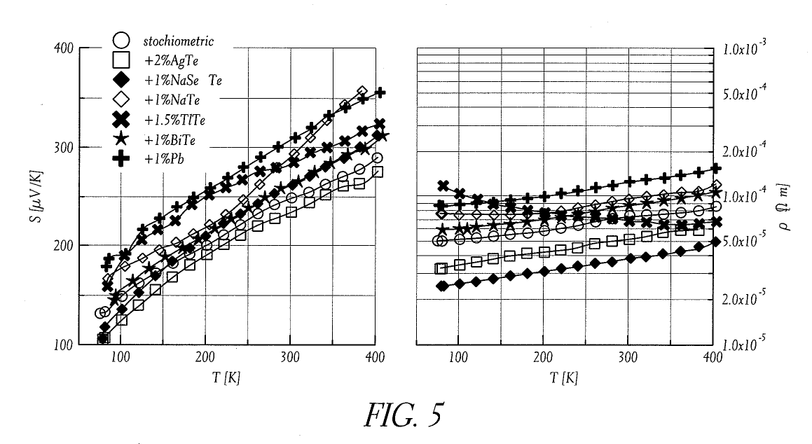

At higher temperatures (T>300 K), the transient flash-diffusivity method was used to calculate κ. Total thermal conductivity was calculated as a product of measured specific heat at constant pressure Cₚ, thermal diffusivity α, and material density. The specific heat shown in FIG. 4(a) was measured on the undoped sample. The results are from two separate instruments: a Quantum Design PPMS was used for data in the 2 K to 300 K temperature range and differential scanning calorimetry provided those in the 300 K to 400 K range. Results in two temperature ranges closely match, reaching Cₚ=0.22 J/g K at and above 300 K. From these measurements, estimated Debye temperature is about θ_{D}=138 K. Thermal diffusivity was measured on about 10-mm-diameter discs with thickness of about 1.2 mm in an Anter FlashLine 3000 system. Results are shown in FIG. 4(b). To calculate thermal conductivity κ, material density of 6.852 g/cm³ was used as measured by the Thermophysical Properties Research Laboratory (TPRL). Error in the measurement of thermal conductivity was caused by thermal diffusivity error (about 5%), but also by uncertainties in Cₚ and density, for a combined estimated error of about 10% over the entire temperature range, and about 7% near room temperature. Galvanomagnetic and thermomagnetic properties were measured on prismatic samples cut from neighboring regions of the ingots, in a standard flow cryostat in the temperature range 80 K to 400 K. Sample dimensions were about 2 mm×2 mm×8 mm. Zero-magnetic-field ρ and S are shown in FIG. 5. Resistivity was measured using the four-wire alternating-current (AC) method. Inaccuracy in sample dimensions, distance between the longitudinal voltage probes, and sample cross section were sources of experimental inaccuracy. The error on the absolute value electrical resistivity was on the order of 8% with the relative error being small. The Seebeck coefficient was measured using static heater and sink method as a ratio of measured voltage and temperature differential, both measured using the same probes. Since Seebeck coefficient does not depend on sample geometry, a main error source was sample nonuniformity.

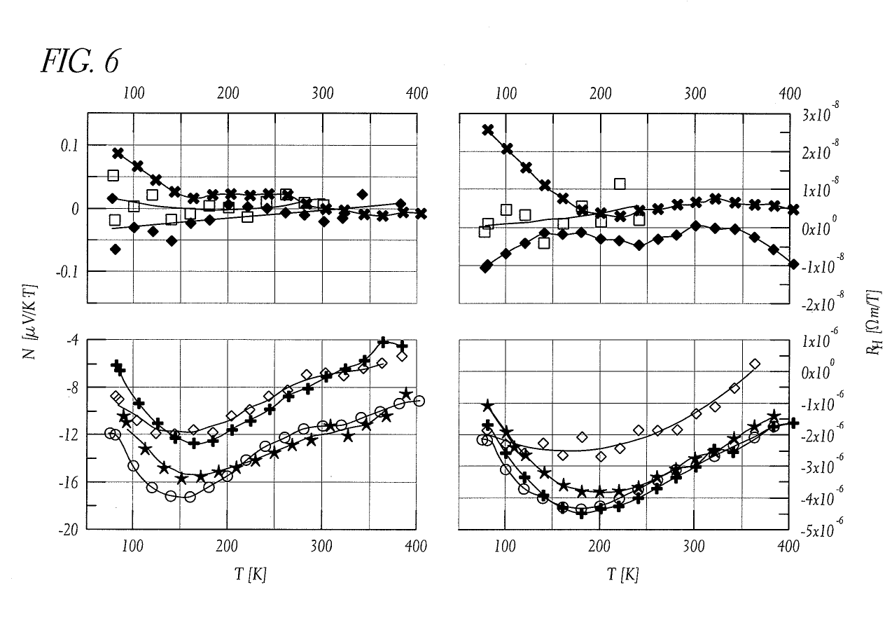

Hall resistivities and adiabatic Nernst-Ettingshausen voltages were measured in transverse magnetic field of −1.5 T to 1.5 T. Hall coefficient R_{H} and isothermal Nernst coefficients were calculated as zero-field slopes in the magnetic field and are reported in FIG. 6. Reported isothermal thermomagnetic effects were deduced from the measured adiabatic ones using conventional methods. Hall coefficient errors were due to inaccuracy in measurement of thickness and are on the order of 3%, while the Nernst coefficient has similar error as ρ due to the inaccuracy in the measurement of the distance between voltage and temperature probes.

Properties of materials doped with AgTe, NaSeco₅Te_{0.5}, NaTe, TlTe, BiTe, and Pb were compared with those of stoichiometric AgSbTe₂. K. Hoang, Atomic and electronic structures of novel ternary and quaternary narrow band-gap semiconductors, Ph.D. thesis, Michigan State University (2007) contains a detailed analysis of galvanomagnetic and thermomagnetic properties in magnetic field of undoped AgSbTe₂. Without being bound by theory, these results (see Table I) indicate that even the nominally undoped material is a partially compensated p-type semiconductor, presumably due to Ag vacancies and that stoichiometric AgSbTe₂ is a two-carrier conduction system with a high concentration of low-mobility holes and low concentration of high-mobility electrons.

TABLE I
Partial Hole and Electron Properties of Undoped AgSbTe₂ as Calculated from
Measured Magnetic Dependence of Galvanomagnetic and Thermomagnetic Properties.

| | | | μᵢ | | Sᵢ | | Nᵢ | |
|---|---|---|---|---|---|---|---|---|
| | n/p (cm⁻³) | | (cm²/Vs) | | (μV/KT) | | (μV/K) | |
| | 80K | 300K | 80K | 300K | 80K | 300K | 80K | 300K |
| Holes | 4.0 × 10¹⁹ | 6.1 × 10¹⁹ | 32 | 11 | 151 | 339 | −0.017 | −0.07 |
| Electrons | 7.8 × 10¹⁵ | 8.0 × 10¹⁶ | 10660 | 2208 | −166 | −92 | −58.35 | −10.76 |

Both holes and electrons contribute to the electrical conductivity C by the addition of partial electron (σₑ) and hole conductivity (σₕ) components as shown in Eq. 1,

σₑ=neμₑ, σₕ=peμₕ, σ=1/ρ=σₑ+σₕ (1)

Here, e is carrier charge, p and n are partial carrier concentrations, and μₑ and μₕ are electron and hole mobilities, respectively. Conductivity is the sum of first-order terms in mobility, unlike R_{H} which is the sum of quadratic terms in mobilities, as shown in Eq. 2.

$${R}_{H} = \frac{- n {μ}_{e}^{2} + p {μ}_{h}^{2}}{n {μ}_{e} + p {μ}_{h}} \qquad ( 2 )$$

Due to the large difference in μₑ and μₕ (Table I) the sign of R_{H} is dominated by high-mobility electrons, although the material is p-type. A large difference in hole and electron effective masses reflects on the carrier mobility difference and the partial Seebeck coefficients Sₕ and Sₑ (Table I). The sign of S is dominated by majority carriers as shown by Eq. 3.

$$S = \frac{{S}_{e} {σ}_{e} + {S}_{h} {σ}_{h}}{{σ}_{e} + {σ}_{h}} \qquad ( 3 )$$

The two-carrier conduction Nernst coefficient of undoped AgSbTe₂ is dominated by the product of differences in partial Seebeck and carrier mobilities, the second term in Eq. 4:

$$N = \frac{\begin{matrix}( {N}_{e} {σ}_{e} + {N}_{h} {σ}_{h} ) ( {σ}_{e} + {σ}_{e} ) + \\ ( {S}_{h} - {S}_{e} ) ( {R}_{Hh} {σ}_{h} - {R}_{He} {σ}_{e} ) {σ}_{e} {σ}_{h}\end{matrix}}{{( {σ}_{e} + {σ}_{h} )}^{2}} \qquad ( 4 )$$

A complex electronic structure yields unusual results reported as “anomalous Hall coefficients” by R. Wolfe, J. H. Wernick, and S. E. Haszko, J. Appl. Phys. Vol. 31, pp. 1959 (1960). Undoped AgSbTe₂ shows positive thermopower and negative Hall coefficient as shown in FIG. 5 and FIG. 6. It also has a high Nernst coefficient, as shown in FIG. 6, because the Nernst coefficient of a two-carrier system is dominated by the second term in the numerator of Eq. 4.

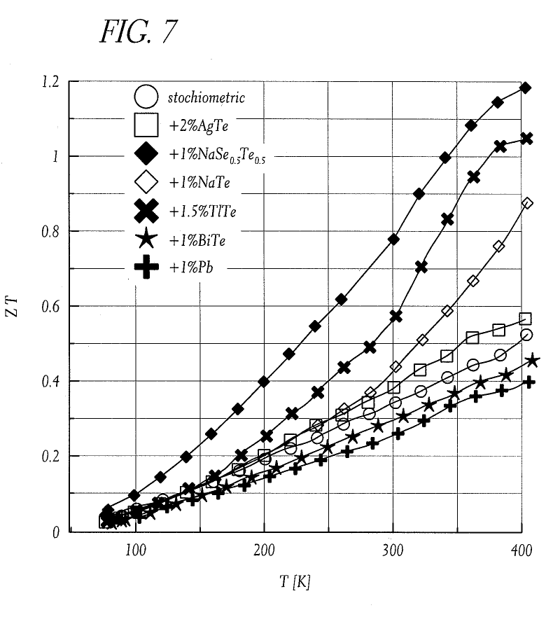

Band-structure calculations predict a large hole effective mass which indicates that the thermoelectric properties of this material can be improved if doped p-type. The measured results from the experiments are in agreement with the band-structure calculations. When doped with AgTe, both p and S decrease, as shown in FIG. 5. This indicates an increase in hole concentration, and is accompanied by a decrease in values of transverse transport properties R_{H} and N. The Hall coefficient decreases due to the enlarged number of low-mobility p-type carriers, which suppress the effect of high-mobility electrons on the sign of the Hall coefficient. Thus, the sign of R_{H} turns positive, as shown in FIG. 6, matching that of the Seebeck coefficient. Doping with AgTe has a similar effect on N, which is now dominated by the first term in the numerator of Eq. 4. Increased hole concentration is accompanied by increased contribution of electronic conductivity to thermal conductivity. FIG. 4(c) shows thermal conductivity higher than that of undoped alloy. This increase in K produces ZT lower than that of pure alloy, as shown in FIG. 7.

Sodium doping introduces fewer carriers than adding Ag. Material doped with NaSe_{0.5}Te_{0.5} had the lowest resistivity of all the prepared samples of this study. The Seebeck coefficient is larger than that of reference sample at temperatures above 150 K, as shown in FIG. 5. Both R_{H} and N of this material indicate diminishing influence of minority electrons. The Hall coefficient is small but remains negative and the Nernst coefficient is small and changes sign at T>340 K, as shown in FIG. 6. Thermal conductivity of this alloy is larger than that of the reference sample, as shown in FIG. 4(c), but is of the same order of magnitude. The figure of merit of AgSbTe₂:NaSe_{0.5}Te_{0.5} reaches a value of ZT=1.2 at 400 K, comparable to that measured by Rosi et al. at 700 K. Doping with NaTe results in an increase in hole concentration; Hall coefficient becomes positive at temperatures above 300 K. Temperature dependence of S differs and this parameter shows an even higher increase but is accompanied by an increase in resistivity. Thermal conductivity remains at about the level of undoped sample so the overall material performance improves with ZT=0.87 at 400 K. Doping with NaTe is less effective than with NaSe_{0.5}Te_{0.5}, as both the resistivity and the Seebeck coefficient are higher. Without being bound by theory, this could be attributable to an extrinsic effect related to sample preparation. In contrast to metallic Na used to prepare samples doped with NaTe, Na₂Se is not prone to oxidization and samples doped with 1% NaSe_{0.5}Te_{0.5} have much lower resistivity, as shown in FIG. 5.

Thallium is routinely used as p-type dopant in PbTe. Introduced into AgSbTe₂ it dopes the material p-type, presumably because the fraction of the TI atoms that substitutes for Sb tends to be monovalent. Hall and Nernst coefficients are positive throughout the temperature range, as shown in FIG. 6. The temperature dependence of the electrical resistivity is not metallic and is different from that of the other samples. The thermopower is increased relative to that of reference sample. There is no indication of an increase in the electronic component of thermal conductivity as measured, and thermal diffusivity and calculated thermal conductivity stay at about the level of AgSbTe₂. Material ZT exceeds unity at measured temperatures, as shown in FIG. 4. To contrast the effects of p-type doping, properties of two samples doped with BiTe and excess Pb were measured. Neither the transverse nor the longitudinal properties of Bi-doped samples change significantly compared with AgSbTe₂. Presumably, Bi substitutes for Sb and is electrically inactive. For Pb-doped samples, the transverse properties remain in essence unchanged from those of undoped AgSbTe₂, but an increase in S is measured, which is compensated by increasing ρ, as shown in FIG. 5. Without being bound by theory, Pb probably substitutes slightly preferentially on the Ag sites, and its overall effect is presumably that of a very inefficient donor. On both samples, ZT stayed at about the level of the undoped material, as shown in FIG. 7.

In certain embodiments, the thermoelectric material comprises a solid solution of two or more ternary compounds. For example, a solid solution of AgSbTe₂ with another ternary compound (e.g., CuSbTe₂) includes, but is not limited to, any mixture of the two ternary compounds in which the concentrations of Ag and Cu are varied continually. For example, a solid solution of AgSbTe₂ and CuSbTe₂ can be expressed by the chemical formula CuᵤAg₁₋ᵤSbTe₂, in which 0≦u≦1. In general, a solid solution of two or more A-B-C₂ compounds can be expressed by A′ᵤA₁₋ᵤ-B-C₂, or A-B′ᵥB₁₋ᵥ-C₂, or A-B-(C′_{w}C_{1-w})₂, or a combination of two or more of these three formulae, with 0<u,v,w<1. Similar notation can be used to express the solid solution of two or more A₁₋ₓB₁₊ᵥC_{2+z} compounds. For certain embodiments described herein, the A′ component comprises at least one of the group consisting of: at least one Group Ia element and at least one Group Ib element, the B′ component comprises at least one of the group consisting of: at least one Group V element and at least one Group VIII element, and the C′ component comprises at least one Group VI element.

Various embodiments have been described above. Although this invention has been described with reference to these specific embodiments, the descriptions are intended to be illustrative of the invention and are not intended to be limiting. Various modifications and applications may occur to those skilled in the art without departing from the true spirit and scope of the invention as defined in the appended claims.

What is claimed is:

1. A thermoelectric material comprising a compound having an elemental formula of A₁₋ₓB_{1+y}C_{2+z} and having a coefficient of thermal expansion greater than 20 parts-per-million per degree Celsius in at least one direction at one or more operating temperatures, wherein the A component of the compound comprises at least one element selected from the group consisting of: at least one Group Ia element and at least one Group Ib element, the B component of the compound comprises at least one element selected from the group consisting of: at least one Group V element and at least one Group VIII element, and the C component of the compound comprises at least one Group VI element, wherein x is between −0.2 and 0.3, y is between −0.2 and 0.4, and z is between −0.2 and 0.8, wherein the A component comprises no more than 95 atomic % silver when the B component comprises antimony and the C component comprises tellurium, wherein the B component comprises no more than 95 atomic % antimony when the A component comprises silver and the C component comprises tellurium, and wherein the C component comprises no more than 95 atomic % tellurium when the A component comprises silver and the B component comprises antimony.

2. The thermoelectric material of claim 1, wherein the at least one Group Ia element comprises at least one element selected from the group consisting of lithium, sodium, potassium, rubidium, and cesium.

3. The thermoelectric material of claim 1, wherein the at least one Group Ib element comprises at least one element selected from the group consisting of copper, silver, and gold.

4. The thermoelectric material of claim 1, wherein the at least one Group V element comprises at least one element selected from the group consisting of phosphorus, arsenic, antimony, and bismuth.

5. The thermoelectric material of claim 1, wherein the at least one Group VIII element comprises at least one element selected from the group consisting of iron, cobalt, and nickel.

6. The thermoelectric material of claim 1, wherein the at least one Group VI element comprises at least one element selected from the group consisting of sulphur, selenium, and tellurium.

7. The thermoelectric material of claim 1, wherein the material is n-type doped with one or more extrinsic dopants selected from the group consisting of: titanium, tantalum, niobium, zinc, maganese, aluminum, gallium, indium, at least Group III element, at least one Group V element, and at least one Group VIII element.

8. The thermoelectric material of claim 1, wherein the material is p-type doped with one or more extrinsic dopants comprising thallium.

9. The thermoelectric material of claim 1, wherein the material is p-type doped with a dopant level greater than about 5×10¹⁹ cm⁻³.

10. A thermoelectric device comprising the thermoelectric material of claim 1.

11. The thermoelectric device of claim 10, wherein the thermolelectric device is an electric power generator, a heat pump, a heat engine, a refrigerator, a temperature controller, or an air conditioner.

12. A thermoelectric material comprising a compound having an elemental formula of A₁₋ₓB_{1+y}C_{2+z} and having a Grüneisen parameter greater than 1.6 at one or more operating temperatures, wherein the A component of the compound comprises at least one element selected from the group consisting of: at least one Group Ia element and at least one Group Ib element, the B component of the compound comprises at least one element selected from the group consisting of: at least one Group V element and at least one Group VIII element, and the C component of the compound comprises at least one Group VI element, wherein x is between −0.2 and 0.3, y is between −0.2 and 0.4, and z is between −0.2 and 0.8, wherein the A component comprises no more than 95 atomic % silver when the B component comprises antimony and the C component comprises tellurium, wherein the B component comprises no more than 95 atomic % antimony when the A component comprises silver and the C component comprises tellurium, and wherein the C component comprises no more than 95 atomic % tellurium when the A component comprises silver and the B component comprises antimony.

13. A thermoelectric material comprising a compound having an elemental formula of A₁₋ₓB_{1+y}C_{2+z} and having a coefficient of thermal expansion greater than 20 parts-per-million per degree Celsius in at least one direction at one or more operating temperatures, wherein the A component of the compound comprises at least one element selected from the group consisting of: at least one Group Ia element and at least one Group Ib element, the B component of the compound comprises at least one element selected from the group consisting of: at least one Group V element and at least one Group VIII element, and the C component of the compound comprises at least one Group VI element, wherein x is non-zero, y is non-zero, and z is non-zero.

14. The thermoelectric material of claim 13, wherein x is between 0.01 and 0.3, y is between 0.01 and 0.4, and z is between 0.01 and 0.8.

15. A thermoelectric material comprising a compound having an elemental formula of A₁₋ₓB_{1+y}C_{2+z} and having a Grüneisen parameter greater than 1.6 at one or more operating temperatures, wherein the A component of the compound comprises at least one element selected from the group consisting of; at least one Group Ia element and at least one Group Ib element, the B component of the compound comprises at least one element selected from the group consisting of: at least one Group V element and at least one Group VIII element, and the C component of the compound comprises at least one Group VI element, wherein x is non-zero, y is non-zero, and z is non-zero.

16. The thermoelectric material of claim 15, wherein x is between 0.01 and 0.3, y is between 0.01 and 0.4, and z is between 0.01 and 0.8.

17. A thermoelectric material comprising a compound having an elemental formula of A₁₋ₓB_{1+y}C_{2+z} and having a polycrystalline structure with at least one crystal having a volume greater than about 0.0001 mm³, wherein the A component of the compound comprises at least one element selected from the group consisting of; at least one Group Ia element and at least one Group Ib element, the B component of the compound comprises at least one element selected from the group consisting of: at least one Group V element and at least one Group VIII element, and the C component of the compound comprises at least one Group VI element, wherein x is between −0.2 and 0.3, y is between −0.2 and 0.4, and z is between −0.2 and 0.8.

18. A thermoelectric material comprising a compound having an elemental formula of A₁₋ₓB_{1+y}C_{2+z}, wherein the A component of the compound comprises at least one element selected from the group consisting of: at least one Group Ia element and at least one Group Ib element, the B component of the compound comprises at least one element selected from the group consisting of: at least one Group V element and at least one Group VIII element, and the C component of the compound comprises at least one Group VI element, wherein x is between −0.2 and 0.3, y is between −0.2 and 0.4, and z is between −0.2 and 0.8, and wherein the thermoelectric properties of the compound are substantially independent of any nanometer-sized inclusions within the compound.

19. A thermoelectric material comprising a compound having an elemental formula of A₁₋ₓB_{1+y}C_{2+z}, wherein the A component of the compound comprises at least one element selected from the group consisting of: at least one Group Ia element and at least one Group Ib element, the B component of the compound comprises at least one element selected from the group consisting of: at least one Group V element and at least one Group VIII element, and the C component of the compound comprises at least one Group VI element, wherein x is between −0.2 and 0.3, y is between −0.2 and 0.4, and z is between −0.2 and 0.8, wherein the compound is doped with a dopant level greater than about 5×10¹⁹ cm⁻³.

20. The thermoelectric material of claim 19, wherein the dopant level is in a range between about 5×10¹⁹ cm⁻³ and about 1×10²¹ cm⁻³.

21. The thermoelectric material of claim 19, wherein the A component comprises Ag, the B component comprises Sb, and the C component comprises Te.

22. The thermoelectric material of claim 21, wherein the compound is p-type doped with at least one dopant selected from the group consisting of: lithium, sodium, indium, gallium, aluminum, thallium, oxygen, sulphur, and selenium.

23. The thermoelectric material of claim 21, wherein the compound is p-type doped such that the compound comprises an excess amount of one or more chalcogen elements.

24. The thermoelectric material of claim 21, wherein the compound is p-type doped to have an atomic concentration of antimony greater than an atomic concentration of silver in the compound and to have an atomic concentration of tellurium less than the sum of an atomic concentration of silver in the compound plus an atomic concentration of antimony in the compound.

25. The thermoelectric material of claim 21, wherein the compound is n-type doped with at least one dopant selected from the group consisting of: titanium, tantalum, niobium, zinc, maganese, aluminum, gallium, indium, at least Group III element, at least one Group V element, and at least one Group VIII element.

26. The thermoelectric material of claim 21, wherein the compound is n-type doped to have an atomic concentration of antimony greater than an atomic concentration of silver in the compound and to have an atomic concentration of tellurium greater than the sum of an atomic concentration of antimony in the compound plus an atomic concentration of silver in the compound.

27. A method of fabricating a thermoelectric material, the method comprising:
placing a plurality of materials in a container, the plurality of materials comprising a first amount of at least one element selected from the group consisting of: at least one Group Ia element and at least one Group Ib element, a second amount of at least one element selected from the group consisting of: at least one Group V element and at least one Group VIII element, and a third amount of at least one Group VI element, wherein the first amount, the second amount, and the third amount have the molar ratios of (1−x):(1+y):(2+z), respectively with x between −0.2 and 0.3, y between −0.2 and 0.4, and z between −0.2 and 0.8;
sealing the plurality of materials within the container under vacuum; and
exposing the materials within the container to a predetermined temperature profile.

28. The method of claim 27, wherein the materials exposed to the predetermined temperature profile form a compound having an elemental formula of A₁₋ₓB_{1+y}C_{2+z}, where A denotes the at least one element selected from the group consisting of: at least one Group Ia element and at least one Group Ib element, B denotes the at least one element selected from the group consisting of: at least one Group V element and the at least one Group VIII element, and C denotes the at least one Group VI element.

29. The method of claim 28, wherein the A component comprises no more than 95 atomic % silver when the B component comprises antimony and the C component comprises tellurium, wherein the B component comprises no more than 95 atomic % antimony when the A component comprises silver and the C component comprises tellurium, and wherein the C component comprises no more than 95 atomic % tellurium when the A component comprises silver and the B component comprises antimony.

30. The method of claim 27, wherein the materials exposed to the predetermined temperature profile form a compound having a coefficient of thermal expansion greater than 20 ppm per degree Celsius in at least one direction at one or more operating temperatures.

31. The method of claim 27, wherein the materials exposed to the predetermined temperature profile form a compound having a Grüneisen parameter greater than 1.6 at one or more operating temperatures.

32. The method of claim 27, wherein the materials exposed to the predetermined temperature profile form a compound having a polycrystalline structure with a plurality of crystallites with volumes greater than about 0.0001 mm³.

33. The method of claim 27, wherein the compound has the elemental formula of Ag₂₂Sb₂₇Te₅₁.

34. The method of claim 33, wherein the compound has a purity of greater than 90%.

35. The method of claim 27, wherein the plurality of materials comprises elemental silver, antimony, and tellurium.

36. The method of claim 27, wherein the plurality of materials comprises Ag₂Te.

37. The method of claim 27, wherein the plurality of materials comprises Sb₂Te₃.

38. The method of claim 27, wherein the predetermined temperature profile comprises;
heating the container to a first temperature at a first rate;
maintaining the container at the first temperature for a first time period;
cooling the container to a second temperature at a second rate;
maintaining the container at the second temperature for a second time period; and
cooling the container to a third temperature at a third rate.

39. The method of claim 38, further comprising furnace rocking during the first time period.

40. A thermoelectric material comprising a solid solution of two or more compounds having an elemental formula of A₁₋ₓB_{1+y}C_{2+z}, wherein the A component of the compound comprises at least one element selected from the group consisting of: at least one Group Ia element or Group Ib element, the B component of the compound comprises at least one element selected from the group consisting of: at least one Group V element or at least one Group VIII element, and the C component of the compound comprises at least one Group VI element, and wherein x is between −0.2 and 0.3, y is between −0.2 and 0.4, and z is between −0.2 and 0.8.
